(19) United States
(12) Patent Application Publication
(10) Pub. No.: US 2025/0125319 A1
(43) Pub. Date: Apr. 17, 2025

(54) STACKED ELECTRONIC STRUCTURE

(71) Applicant: CYNTEC CO., LTD., HSINCHU (TW)

(72) Inventors: Bau Ru Lu, HSINCHU (TW); Yueh Lun Lee, HSINCHU (TW)

(21) Appl. No.: 18/912,626

(22) Filed: Oct. 11, 2024

Related U.S. Application Data
(60) Provisional application No. 63/544,147, filed on Oct. 13, 2023.

(51) Int. Cl. H01L 25/16; H01L 23/31; H01L 23/373; H01L 23/498; H01L 29/78

(52) U.S. Cl. CPC H01L 25/16; H01L 23/3736; H01L 23/49811; H10D 1/20; H01L 23/3107; H10D 30/60

(57) ABSTRACT

A stacked electronic structure, wherein a molding body encapsulates a first active device with a first electrode on a top surface of the first active device and a second electrode on a bottom surface of the first active device; and a magnetic device disposed over the molding body and comprising a first inductor, wherein the second electrode of the first active device is electrically connected to the substrate, and the first electrode of the first active device tis electrically connected to the first inductor.

### CROSS-REFERENCES TO RELATED APPLICATIONS

The present application claims the benefit of U.S. Provisional Application Ser. No. 63/544,147 filed on Oct. 13, 2023, which is hereby incorporated by reference herein and made a part of the specification.

### BACKGROUND OF THE INVENTION

### I. Field of the Invention

The invention relates to an electronic structure and, in particular, to a stacked electronic structure.

### II. Description of the Related Art

Electronic structures, such as power modules and DC-DC converters, typically include electronic devices having interconnecting circuitry electrically connected to a substrate. The devices are coupled to leads for connection to conductive patterns and/or other electronic assemblies.

One conventional approach for reducing the surface area occupied by the electronic structures in compact electronic products is to stack the assembled devices. However, the heat generated from the coil is hard to dissipate.

Furthermore, the heat generated by the stacked electronic devices is also hard to dissipate.

Accordingly, there is demand for a better solution to solve these problems.

### SUMMARY OF THE INVENTION

In one embodiment of the present invention, a stacked electronic structure is disclosed, wherein the stacked electronic structure comprises: a substrate, wherein a plurality of electronic devices are disposed on the substrate, wherein a molding body encapsulates the plurality of electronic devices, wherein the plurality of electronic devices comprises a first active device, wherein a first electrode of a first active device is on a top surface of the first active device and a second electrode of the first active device is on a bottom surface of the first active device; and a magnetic device, comprising a magnetic body disposed over the molding body and a first inductor disposed in the magnetic body, wherein the second electrode of the first active device is electrically connected to the substrate, and the first inductor is electrically connected to the first electrode of the first active device.

In one embodiment, the first active device is a first MOSFET.

In one embodiment, the first inductor is made of a flat metal wire.

In one embodiment, a second active device is disposed on the substrate, wherein a first electrode of a second active device is on a top surface of the second active device and a second electrode of the second active device is on a bottom surface of the second active device, wherein a second inductor is disposed in the magnetic body, wherein the second electrode of the second active device is electrically connected to the substrate, and the second inductor is electrically connected to the first electrode of the second active device.

In one embodiment, the first active device is a first MOSFET, and the second active device is a second MOSFET.

In one embodiment, the second inductor is made of a flat metal wire.

In one embodiment, a first conductive pillar is disposed on and electrically connected to the substrate, wherein the molding body encapsulates the first active device and the first conductive pillar, wherein the first inductor is electrically connected to the first electrode of the first active device and the first conductive pillar.

In one embodiment, a first conductive pillar and a second conductive pillar are disposed on and electrically connected to the substrate, wherein the molding body encapsulates the first active device, the second active device, the first conductive pillar and the second conductive pillar, wherein the first inductor is electrically connected to the first electrode of the first active device and the first conductive pillar, and the second inductor is electrically connected to the second electrode of the second active device and the second conductive pillar.

In one embodiment, a first conductive pillar and a second conductive pillar are disposed on and electrically connected to the substrate, wherein the molding body encapsulates the first MOSFET, the second MOSFET, the first conductive pillar and the second conductive pillar, wherein a first electrode of a first MOSFET is on a top surface of the first MOSFET and a second electrode of a second MOSFET is on a top surface of the second MOSFET, wherein the first conductive wire is electrically connected to the first electrode of the first MOSFET and the first conductive pillar, and the second conductive wire is electrically connected to the second electrode of the second MOSFET and the second conductive pillar.

In one embodiment, a portion of the first inductor is not covered by the magnetic body for connecting with a heatsink.

In one embodiment, a top surface of the first inductor is not covered by the magnetic body for connecting with the heatsink.

In one embodiment, a lateral surface of the first inductor is not covered by the magnetic body for connecting with the heatsink.

In one embodiment, the stacked electronic structure as claimed in claim 10, wherein a pad is disposed on said portion of the first inductor for connecting with the heatsink.

In one embodiment, the bottom surface of a first electrode of the first inductor and the bottom surface of a second electrode of the first inductor are not coplanar.

In one embodiment of the present invention, a stacked electronic structure is disclosed, wherein the stacked electronic structure comprises: a substrate, wherein a plurality of electronic devices are disposed on the substrate, wherein a molding body encapsulates the plurality of electronic devices; and a magnetic device, comprising a magnetic body disposed over the molding body and a first inductor disposed in the magnetic body, wherein a portion of the first inductor is not covered by the magnetic body for connecting with a heatsink.

In one embodiment, a pad is disposed on said portion of the first inductor for connecting with the heatsink.

In one embodiment, a top surface of the first inductor is not covered by the magnetic body for connecting with a heatsink.

In one embodiment, a first lateral surface of the first inductor is not covered by the magnetic body for connecting with a first heatsink.

In one embodiment, a second lateral surface of the first inductor is not covered by the magnetic body for connecting with a second heatsink, wherein the first lateral surface and the second lateral surface are two opposite lateral surfaces of the first inductor.

In one embodiment, the heatsink is a copper plate.

In one embodiment of the present invention, a stacked electronic structure is disclosed, wherein the stacked electronic structure comprises: a substrate, wherein a plurality of electronic devices are disposed on the substrate, wherein a molding body encapsulates the plurality of electronic devices; and a magnetic device, comprising a magnetic body disposed over the molding body and a first inductor disposed in the magnetic body, wherein the bottom surface of a first electrode of the first inductor and the bottom surface of a second electrode of the first inductor are not coplanar.

In one embodiment, a vertical distance between the bottom surface of a first electrode of the first inductor and the bottom surface of a second electrode of the first inductor is greater than xxx um.

the copper plate is electrically connected to a ground.

In one embodiment, wherein a copper plate encapsulates a top surface of magnetic device.

In one embodiment, wherein a copper plate encapsulates a lateral surface of the magnetic device.

In one embodiment, the molding body encapsulates the conductive pillars with a top surface of each of the conductive pillars exposed from the molding body.

### BRIEF DESCRIPTION OF THE DRAWINGS

The present invention can be more fully understood by reading the subsequent description and examples with references made to the accompanying drawings, wherein:

FIG. 1A-1E shows a 3D view of a stacked electronic structure in accordance with one embodiment of the invention;

FIG. 2 shows a 3D view of a stacked electronic structure in accordance with one embodiment of the invention;

FIG. 3 shows a 3D view of a stacked electronic structure in accordance with one embodiment of the invention;

FIG. 4 shows a 3D view of a stacked electronic structure in accordance with one embodiment of the invention;

FIG. 5 shows a 3D view of a stacked electronic structure in accordance with one embodiment of the invention;

FIG. 6 shows a cross-section view of a stacked electronic structure in accordance with one embodiment of the invention.

### DETAILED DESCRIPTION OF THE INVENTION

It is understood that the following disclosure provides many different embodiments, or examples, for implementing different features of the invention. Specific examples of devices and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features are formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

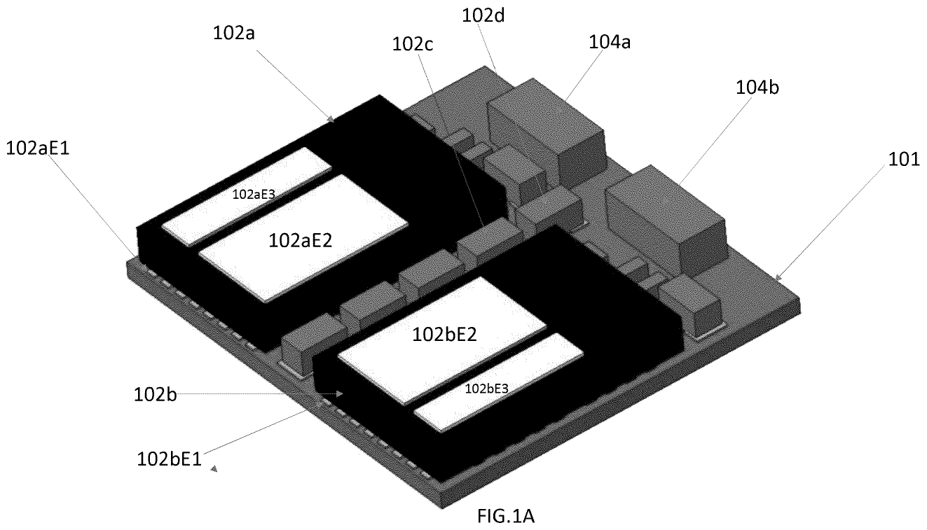

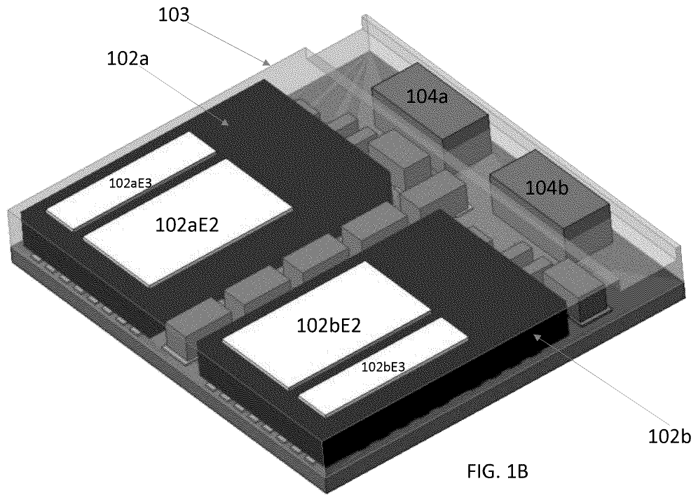

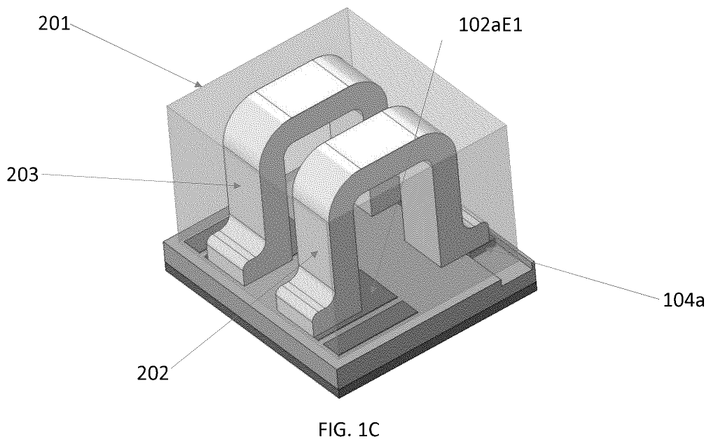

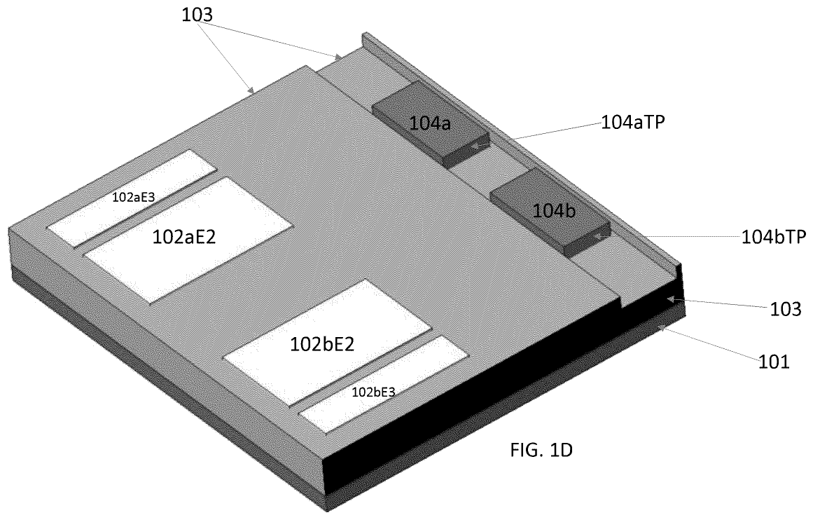

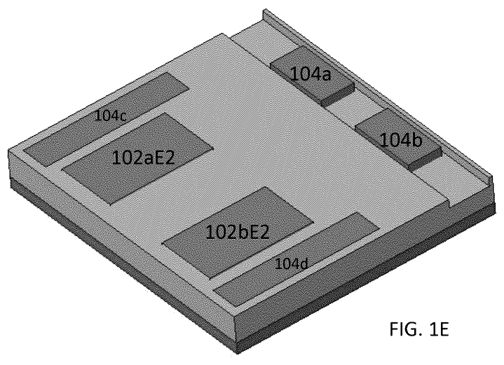

FIG. 1A is a 3D view of a PCB with devices thereon of a stacked electronic structure in accordance with one embodiment of the invention; FIG. 1B is a 3D view by adding a molding body to encapsulate the devices on the PCB in accordance with one embodiment of the invention; FIG. 1C is a 3D view by adding a magnetic device on the molding body in accordance with one embodiment of the invention; As shown in FIG. 1A-1C, wherein the electronic structure comprises a substrate 101, wherein a plurality of electronic devices 102a, 102b are disposed on the substrate 101, wherein a molding body 103 encapsulates the plurality of electronic devices 102a, 102b, wherein the plurality of electronic devices comprises a first active device 102a, wherein a first electrode 102aE1 of the first active device 102a is on a top surface of the first active device 102a and a second electrode 102aE2 of the first active device 102a is on a bottom surface of the first active device 102a; and a magnetic device 200, comprising a magnetic body 201 disposed over the molding body 103 and a first inductor 202 disposed in the magnetic body 201, wherein the second electrode 102aE2 of the first active device 102a is electrically connected to the substrate 101, and the first inductor 202 is electrically connected to the first electrode 102aE1 of a first active device 102a.

In one embodiment, an adhesive layer is disposed on the first active device 102a and the second active device 102b to fix the first active device 102a and the second active device 102b.

In one embodiment, the first electrode 102aE1 of the first active device 102a is exposed from the molding body.

In one embodiment, the first active device is a first MOSFET.

In one embodiment, the first inductor 202 is made of a flat metal wire.

In one embodiment, a second active device 102b is disposed on the substrate, wherein a first electrode 102bE1 of a second active device 102b is on a top surface of the second active device 102b and a second electrode 102bE2 of the second active device 102b is on a bottom surface of the second active device 102b, wherein a second inductor 203 is disposed in the magnetic body 201, wherein the second electrode 102bE2 of the second active device 102b is electrically connected to the substrate 101, and the second inductor 203 is electrically connected to the first electrode 102bE1 of a second active device 102b.

In one embodiment, the first active device 102a is a first MOSFET, and the second active device is a second MOSFET.

In one embodiment, the second inductor 203 is made of a flat metal wire.

In one embodiment, a first conductive pillar 104a is disposed on and electrically connected to the substrate 101, wherein the molding body 103 encapsulates the first active device 102a and the first conductive pillar 104a, wherein the first inductor 202 is electrically connected to the first electrode 102aE1 of the first active device 102a and the first conductive pillar 104a.

In one embodiment, a first conductive pillar 104a and a second conductive pillar 104b are disposed on and electrically connected to the substrate 101, wherein the molding body 103 encapsulates the first active device 102a, the second active device 102b, the first conductive pillar 104a and the second conductive pillar 104b, wherein the first inductor 202 is electrically connected to the first electrode 102aE1 of the first active device 102a and the first conductive pillar 104a, and the second inductor 203 is electrically connected to the second electrode 102bE2 of the second active device 102b and the second conductive pillar 104b.

In one embodiment, a portion of the first inductor 202 is not covered by the magnetic body 103 for connecting with a heatsink.

In one embodiment, as shown in FIG. 1D, a ground pad 102aE3 of the first active device 102a is on a top surface of the first active device 102a.

In one embodiment, as shown in FIG. 1D, a ground pad 102bE3 of the second active device 102b is on a top surface of the first active device 102b.

In one embodiment, as shown in FIG. 1E, the first electrode 102aE1 of the first active device 102a is exposed from a top surface of the molding.

In one embodiment, as shown in FIG. 1E, the first electrode 102bE1 of the second active device 102b is exposed from a top surface of the molding.

In one embodiment, as shown in FIG. 1E, a pad of the conductive pillar 104c is exposed from a top surface of the molding.

In one embodiment, as shown in FIG. 1E, a pad of the conductive pillar 104d is exposed from a top surface of the molding.

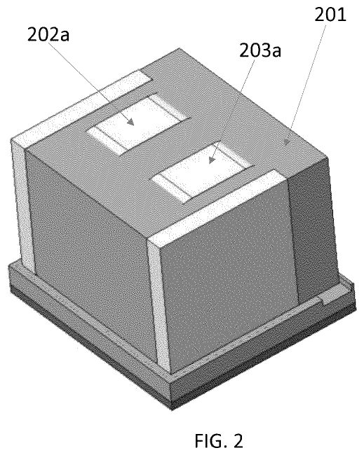

In one embodiment, as shown in FIG. 2, a top surface 202a of the first inductor 202 is not covered by the magnetic body 103 for connecting with a heatsink.

In one embodiment, as shown in FIG. 2, a top surface 203a of the second inductor 203 is not covered by the magnetic body 103 for connecting with a heatsink.

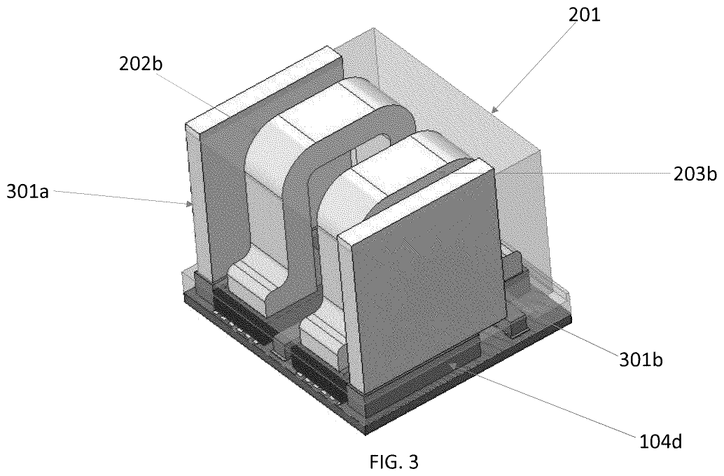

In one embodiment, as shown in FIG. 3, a lateral surface 202b of the first inductor 202 is not covered by the magnetic body 103 for connecting with a heatsink 301a.

In one embodiment, as shown in FIG. 3, a lateral surface 203b of the second inductor 203 is not covered by the magnetic body 103 for connecting with a heatsink 301b.

In one embodiment, a pad is disposed on said portion of the first inductor 202 for connecting with a heatsink.

In one embodiment, the bottom surface of a first electrode of the first inductor and the bottom surface of a second electrode of the first inductor are not coplanar.

In one embodiment, the present invention provides a stacked electronic structure, wherein stacked electronic structure comprises: a substrate 101, wherein a plurality of electronic devices 102a, 102b are disposed on the substrate 101, wherein a molding body 103 encapsulates the plurality of electronic devices 102a, 102b; and a magnetic device 200, comprising a magnetic body 201 disposed over the molding body 103 and a first inductor 202 disposed in the magnetic body 201, wherein a portion of the first inductor 202 is not covered by the magnetic body 201 for connecting with a heatsink.

In one embodiment, a pad is disposed on said portion of the first inductor for connecting with the heatsink.

In one embodiment, a top surface of the first inductor is not covered by the magnetic body for connecting with a heatsink.

In one embodiment, a first lateral surface of the first inductor is not covered by the magnetic body for connecting with a first heatsink.

In one embodiment, a second lateral surface of the first inductor is not covered by the magnetic body for connecting with a second heatsink, wherein the first lateral surface and the second lateral surface are two opposite lateral surfaces of the first inductor.

In one embodiment, the heatsink is a copper plate.

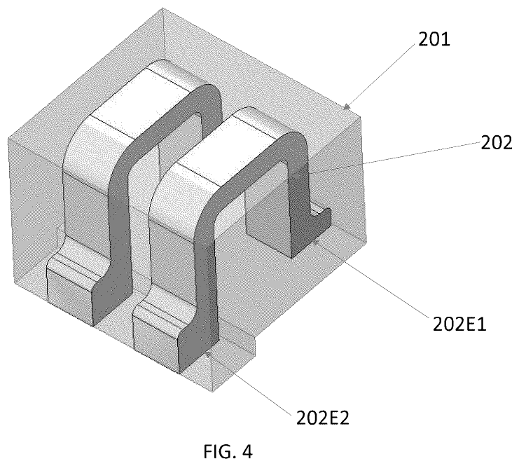

In one embodiment, as shown in FIG. 4, the present invention provides a stacked electronic structure, wherein stacked electronic structure comprises: a substrate 101, wherein a plurality of electronic devices 102a, 102b are disposed on the substrate 101, wherein a molding body 103 encapsulates the plurality of electronic devices 102a, 102b; and a magnetic device 200, comprising a magnetic body 201 disposed over the molding body 103 and a first inductor 202 disposed in the magnetic body 201, wherein the bottom surface of a first electrode 202E1 of the first inductor 202 and the bottom surface of a second electrode 202E2 of the first inductor 202 are not coplanar.

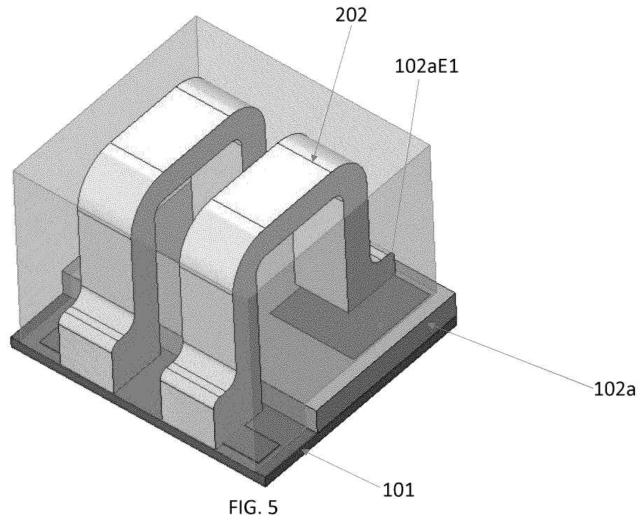

In one embodiment, as shown in FIG. 5, the bottom surface of a first electrode 202E1 of the first inductor 202 is disposed on the electrode on the top surface of a MOSFET, and the bottom surface of a second electrode 202E2 of the first inductor 202 is disposed on a pad on the substrate.

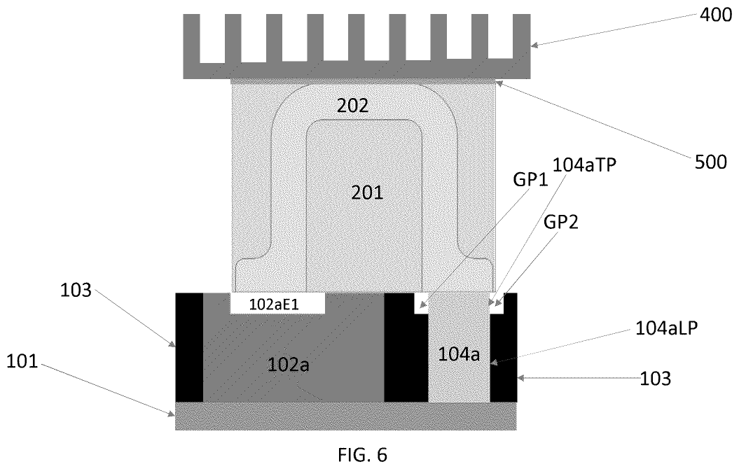

In one embodiment, as shown in FIG. 6, the present invention provides a stacked electronic structure, wherein stacked electronic structure comprises: a substrate, wherein a first active device and a first conductive pillar are disposed on the substrate; a molding body, encapsulating the first active device and the first conductive pillar, wherein a first electrode of the first active device is disposed on a top surface of the first active device, wherein an upper portion 104aTP of the first conductive pillar 104 is not in contact with the molding body and a lower portion 104aLP of the first conductive pillar 104 is embedded inside the molding body; a magnetic device 201, comprising a magnetic body 201 disposed over the molding body 203 and a first inductor 202 disposed in the magnetic body 201, wherein a first terminal of the first inductor 202 is electrically connected to the first electrode 102aE1 of the first active device 102a and a second terminal of the first inductor 202 is electrically connected to the first conductive pillar 104.

In one embodiment, there is a first gap GP1 between a first lateral surface of the first conductive pillar 104 and a first portion of the molding body 103 that is facing the first lateral surface of the first conductive pillar 104.

In one embodiment, there is a second gap GP2 between a second lateral surface of the first conductive pillar and a second portion of the molding body that is facing the second lateral surface of the first conductive pillar.

In one embodiment, a heatsink 400 is disposed on a top surface of the inductor 202.

In one embodiment, an insulating layer is disposed between the inductor and the a heatsink 400.

In one embodiment, as shown in FIG. 1D, the present invention provides a stacked electronic structure, wherein stacked electronic structure comprises: a substrate, wherein a first active device and a first conductive pillar are disposed on the substrate; a molding body, encapsulating the first active device and the first conductive pillar, wherein a first electrode of the first active device is disposed on a top surface of the first active device, wherein the upper portion of the first conductive pillar and an upper portion of a second conductive pillar are disposed in a groove of the molding body; a magnetic device 201, comprising a magnetic body 201 disposed over the molding body 203 and a first inductor 202 disposed in the magnetic body 201, wherein a first terminal of the first inductor 202 is electrically connected to the first electrode 102aE1 of the first active device 102a and a second terminal of the first inductor 202 is electrically connected to the first conductive pillar 104.

From the foregoing, it will be appreciated that, although specific embodiments have been described herein for purposes of illustration, various modifications may be made without deviating from the spirit and scope of the disclosure. Furthermore, where an alternative is disclosed for a particular embodiment, this alternative may also apply to other embodiments even if not specifically stated.

What is claimed is:

1. A stacked electronic structure, comprising:
a substrate, wherein a plurality of electronic devices are disposed on the substrate, wherein a molding body encapsulates the plurality of electronic devices, wherein the plurality of electronic devices comprises a first active device, wherein a first electrode of a first active device is on a top surface of the first active device and a second electrode of the first active device is on a bottom surface of the first active device; and
a magnetic device, comprising a magnetic body disposed over the molding body and a first inductor disposed in the magnetic body, wherein the second electrode of the first active device is electrically connected to the substrate, and the first inductor is electrically connected to the first electrode of the first active device.

2. The stacked electronic structure as claimed in claim 1, wherein the first active device is a first MOSFET.

3. The stacked electronic structure as claimed in claim 1, wherein the first inductor is made of a flat metal wire.

4. The stacked electronic structure as claimed in claim 1, wherein a second active device is disposed on the substrate, wherein a first electrode of a second active device is on a top surface of the second active device and a second electrode of the second active device is on a bottom surface of the second active device, wherein a second inductor is disposed in the magnetic body, wherein the second electrode of the second active device is electrically connected to the substrate, and the second inductor is electrically connected to the first electrode of the second active device.

5. The stacked electronic structure as claimed in claim 4, wherein the first active device is a first MOSFET, and the second active device is a second MOSFET.

6. The stacked electronic structure as claimed in claim 1, wherein a first conductive pillar is disposed on and electrically connected to the substrate, wherein the molding body encapsulates the first active device and the first conductive pillar, wherein the first inductor is electrically connected to the first electrode of the first active device and the first conductive pillar.

7. The stacked electronic structure as claimed in claim 4, wherein a first conductive pillar and a second conductive pillar are disposed on and electrically connected to the substrate, wherein the molding body encapsulates the first active device, the second active device, the first conductive pillar and the second conductive pillar, wherein the first inductor is electrically connected to the first electrode of the first active device and the first conductive pillar, and the second inductor is electrically connected to the second electrode of the second active device and the second conductive pillar.

8. The stacked electronic structure as claimed in claim 1, wherein a portion of the first inductor is not covered by the magnetic body for connecting with a heatsink.

9. The stacked electronic structure as claimed in claim 8, wherein a top surface of the first inductor is not covered by the magnetic body for connecting with the heatsink.

10. The stacked electronic structure as claimed in claim 8, wherein a lateral surface of the first inductor is not covered by the magnetic body for connecting with the heatsink.

11. The stacked electronic structure as claimed in claim 1, wherein the bottom surface of a first electrode of the first inductor and the bottom surface of a second electrode of the first inductor are not coplanar.

12. A stacked electronic structure, comprising:
a substrate, wherein a plurality of electronic devices are disposed on the substrate, wherein a molding body encapsulates the plurality of electronic devices; and
a magnetic device, comprising a magnetic body disposed over the molding body and a first inductor disposed in the magnetic body, wherein a portion of the first inductor is not covered by the magnetic body for connecting with a heatsink.

13. The stacked electronic structure as claimed in claim 12, wherein a top surface of the first inductor is not covered by the magnetic body for connecting with a heatsink.

14. The stacked electronic structure as claimed in claim 12, wherein a first lateral surface of the first inductor is not covered by the magnetic body for connecting with a first heatsink.

15. The stacked electronic structure as claimed in claim 12, wherein the heatsink is a copper plate.

16. A stacked electronic structure, comprising:
a substrate, wherein a plurality of electronic devices are disposed on the substrate, wherein a molding body encapsulates the plurality of electronic devices; and
a magnetic device, comprising a magnetic body disposed over the molding body and a first inductor disposed in the magnetic body, wherein the bottom surface of a first electrode of the first inductor and the bottom surface of a second electrode of the first inductor are not coplanar.

17. The stacked electronic structure as claimed in claim 16, wherein the bottom surface of the first electrode of the first inductor is disposed on an electrode on a top surface of a MOSFET, and the bottom surface of a second electrode of the first inductor is disposed on the substrate.

18. A stacked electronic structure, comprising:
a substrate, wherein a first active device and a first conductive pillar are disposed on the substrate;
a molding body, encapsulating the first active device and the first conductive pillar, wherein a first electrode of the first active device is disposed on a top surface of the first active device, wherein an upper portion of the first conductive pillar is not in contact with the molding body and a lower portion of the first conductive pillar is embedded inside the molding body;
a magnetic device, comprising a magnetic body disposed over the molding body and a first inductor disposed in the magnetic body, wherein a first terminal of the first inductor is electrically connected to the first electrode of the first active device and a second terminal of the first inductor is electrically connected to the first conductive pillar.

19. The stacked electronic structure as claimed in claim 18, wherein there is a first gap between a first lateral surface of the first conductive pillar and a first portion of the molding body that is facing the first lateral surface of the first conductive pillar.

20. The stacked electronic structure as claimed in claim 18, wherein the upper portion of the first conductive pillar is disposed in a groove of the molding body.
